(19) United States
(12) Patent Application Publication
(10) Pub. No.: US 2024/0282886 A1
(43) Pub. Date: Aug. 22, 2024

(54) OPTOELECTRONIC DEVICE AND METHOD FOR PROCESSING THE SAME

(71) Applicant: ams-OSRAM Intemational GmbH, Regensburg (DE)

(72) Inventor: Heng Wang, Eriskirch (DE)

(21) Appl. No.: 18/571,570

(22) PCT Filed: Jun. 18, 2021
(86) PCT No.: PCT/EP2021/066697

§ 371 Date: Dec. 18, 2023

(51) Int. Cl. H01L 33/06; H01L 33/00; H01L 33/24; H01L 33/30

(52) U.S. Cl. CPC H01L 33/06; H01L 33/0062; H01L 33/24; H01L 33/305

(57) ABSTRACT

In an embodiment an optoelectronic device includes a semiconductor body with a layer stack including a first n-doped layer, a quantum well structure arranged on the first n-doped layer, and a p-doped layer arranged on the quantum well structure, wherein the quantum well structure extends along a lateral plane within the first region of the layer stack, wherein the quantum well structure extends within the second region on an inclined surface of one of the n-doped layer and p-doped layer with regards to the lateral plane to the sidewall of the layer stack such that a thickness of the quantum well structure within the second region is smaller than a thickness of the quantum well structure within the first region, and wherein a doping concentration of the n-doped layer in the second region is lower that a doping concentration in the first region.

### CROSS-REFERENCE TO RELATED APPLICATIONS

This patent application is a national phase filing under section 371 of PCT/EP2021/066697, filed Jun. 18, 2021, which is incorporated herein by reference in its entirety.

### TECHNICAL FIELD

The present invention refers to an optoelectronic device and to a method for processing the same.

### BACKGROUND

During manufacturing of small and very small optoelectronic devices referred to as μ-LEDs, mesa structures are defined and generated in order to separate the various optoelectronic components from each other. Along those mesa structures, the devices may be separated. In small and very small devices, the area in-between a surrounding mesa and the circumference of the mesa itself results in a small area/circumference ratio, i.e. the edges of the optoelectronic component are relatively large compared to the enclosed area.

This results in a relatively large quantity of non-radiating recombination centers along the edges due to crystal damages, surface effects and other effects. Consequently, the internal quantum efficiency (IQE) given by the ratio of radiating recombination/non-radiating recombination drops as the device size decreases. Red emitting μ-LEDs based on the InGaAlP material system are suffering the most from this problem, because the surface re-combination velocity and carrier diffusion length are much higher than for InGaN. Consequently, highly efficient μ-LEDs with dimensions smaller than 30 μm has been proven difficult to realize.

To counter the above effect, it was proposed to increase the efficiency of very small InGaAlP optoelectronic devices by diffusion of Zn to achieve quantum well intermixing (QWI).

Such QWI occurs in an area belonging to an outer region of the optoelectronic device defined in subsequent process steps. The QWI enlarges the band gap of the quantum wells in this outer region close to the edges of the mesa and the sidewall of the device, so that the charge carriers in the quantum wells can no longer reach the outer device surface close to the quantum wells, thus increasing the efficiency of very small InGaAlP LEDs.

QWI has provided a significant improvement of efficiency of μ-LEDs, especially at low driving currents. However, there are indications that surface recombination is reduced but not completely suppressed.

It is therefore an object of the present disclosure to improve the efficiency for optoelectronic components further.

### SUMMARY

The concept the inventor proposes is to prevent the carriers in the quantum wells to the surface by growing thinner titled quantum wells near the mesa structure or sidewalls. The tilted quantum wells are thinner than in the center of the μ-LED and therefore comprise a higher bandgap. Therefore, charge carriers are prevented to the sidewall surface by the barrier created by the difference of the bandgaps between the central quantum wells and the tilted thin quantum wells. This approach reduces the surface recombination and achieves high efficiency of the μ-LED. In combination with additional Zn diffusion close to the sidewall in order to generate QWI in such areas an even higher improved efficiency is achieved.

In an aspect, an optoelectronic device is provided, comprising a semiconductor body with a layer stack. A first region and a surrounding second region extending to a sidewall of the layer stack is defined. The layer stack also comprises a first n-doped layer, a quantum well structure arranged on the first n-doped layer and a p-doped layer arranged on the quantum well structure.

In accordance with the present invention, the quantum well structure extends along a lateral plane on top of the first n-doped layer within the first region and also extends within the second region on an inclined surface of one of the n-doped layer and p-doped layer with regards to the lateral plane to the sidewall of the layer stack. In other words, the quantum well structure follows an inclined surface of one of the doped layers and particularly the n-doped layer. As a result and due to the inclination, the thickness of the quantum well structure within the second region is smaller than a thickness of the quantum well structure within the first region.

In some aspects, the bandgap of the quantum well structure in the first region is smaller than a bandgap of the quantum well structure in the second region. Hence, charge carriers are facing a larger bandgap in the second region adjacent to the mesa and sidewalls and are effectively suppressed from reaching said area.

The quantum well structure may comprise a first quantum well and a second quantum well separated by a quantum well barrier. In this regard, the quantum well structure may comprise a multi-quantum-well, in which a plurality of quantum wells and a plurality of quantum well barriers are stacked on top of each other.

In some aspects, the quantum well structure comprises an intrinsic layer at least in the first region adjacent to the n-doped and/or p-doped layer. In other words, an intrinsic layer may be arranged between the respective doped layers and the quantum well structure within the first region.

The thickness of the resulting quantum well structure is different due to the inclination of the doped layer. The thickness of the quantum well structure within the second region is based on an inclination angle between the inclined surface and the lateral plane. In this regard, the diameter of the inclined surface is changing and increasing with increasing distance to the quantum well structure. Particularly, the diameter of the inclined surface parallel to lateral plane increases with increasing distance towards the quantum well structure within the first region.

In some other aspects, the dopant concentration within the n-doped layer having the inclined surface may vary. In this regard, it can be useful to ensure a high concentration close to the planar top surface, as the quantum well structure is suited for radiant recombination. Consequently, the inclined surface n-doped region and/or an area adjacent to inclined surface n-doped region within the second region may comprises a smaller dopant concentration than a dopant concentration in the n-doped layer adjacent to the quantum well structure in the first region.

In some other aspects, the sidewall of the layer stack comprises a mesa structure. The doped layer may comprise different or the same base materials, which as a non-limiting example can be selected form one or more of GaN, AlGaN, AlGaInP, AlGaInN and AlGaP. Other material may also be used. The width of the second region need to be adjusted according to different materials.

Some further aspects concern an additional QWI thus further improving the desired effect of preventing charge carrier from reaching the outer edges. In some aspects, a p-type dopant is deposited in the quantum well structure within the second region, causing a quantum well intermixing thereof. The p-dopant may be Zn diffused onto the quantum well structure form the p-doped layer side. In some further aspects, the p-type dopant extends partially into the n-doped layer causing a shift of a depletion region towards the n-doped layer.

Some other aspects concern a method for processing an optoelectronic device. In a first step of the proposed method, a growth substrate is provided. Then a first doped and particularly n-doped layer stack is deposited on the growth substrate. The first doped layer stack is mesa-structured to provide a top portion surrounded by an inclined sidewall having an angle of less than 90° and in particular in the range of 40° to 75°. A quantum well structure is subsequently deposited on the mesa-structured first doped layer, such that a thickness of the quantum well structure on the inclined sidewall is smaller than a thickness of the quantum well structure on the top portion.

During deposition of the quantum well structure, material is arranged on the top layer and the inclined surface resulting in a larger deposition rate on the top surface of the first layer stack than on the sidewalls. Hence, the thickness of the quantum well structure on the inclined sidewall is reduced compared to the thickness on top. A second doped, particularly p-doped layer stack is provided on the quantum well structure. The p-doped layer stack may comprise a planar surface or after deposition, its surface may be planarized. Subsequently, a structured mask is deposited on the second doped layer stack and subsequently mesa structured to provide sidewalls thereof exposing edge portions of the quantum well structure on the inclined surface.

The resulting structure provides an efficient change in the bandgap of the quantum well on the inclined surface, preventing charge carriers from reaching the mesa edges. In some further aspects, the step of mesa-structuring the first doped layer stack comprises a step of depositing a first mask layer on the first doped layer stack followed by a step of structuring the first mask layer such that areas of the first doped layer stack surrounding the top portion are exposed. Then material in the exposed areas is removed to form the inclined surface. The removal may be non-uniformous in that more material is removed at larger distances from remaining structured mask material. This process will generate inclined sidewalls of the first doped layer.

In a similar manner, the second mesa-structure, defining the shape of the optoelectronic device may be processed. In an aspect, depositing a structured mask on the second doped layer stack comprises the step of depositing a second mask layer on the second doped layer stack. The second mask layer is subsequently structured such that areas of the second doped layer stack, which in projection surrounds the top portion and areas surrounding the top portion are exposed. Finally, material is removed in the exposed areas.

For the generation of the doped layer, different deposition methods, for example MOCVD or MOVPE processes can be used. During the deposition of the base material for the respective doped layers, a concentration of the respective dopant may vary and allow adjustment of the doping tape and its concentration.

In this regard, wherein the step of depositing the first doped layer stack and/or the second doped layer stack may comprise depositing an intrinsic layer of a base material of the respective first and/or second doped layer stack, the intrinsic layer being adjacent to the quantum well structure.

Some further aspects concern the generation of the quantum well structure. For example, the step of depositing a quantum well structure may comprise the step of depositing one or more quantum well layers between respective quantum well barrier layers, the quantum well barrier layers having a larger bandgap than the quantum well layers.

As pointed out already, the thickness of the quantum well layer structure is based on the inclination angle between the sidewalls of the first doped layer stack and a top planar surface of the first doped layer stack. Consequently, the bandgap difference between quantum well structure on top of the first doped layer and the quantum well structure on the sidewalls can be adjusted by the inclination angle, which in turn can be controlled during the first mesa structuring.

Further to this aspect, an angle between the sidewalls of the optoelectronic device and the top surface of the first doped layer stack is larger than an angle between the inclined sidewalls of the first doped layer stack and the top surface of the first doped layer stack. In other words, the optoelectronic device has steeper sidewalls, than the sidewalls of the first doped layer on which the inclined quantum well structure is arranged.

Some further aspects relate to the process of generating an additional supportive QWI close to the mesa of the device. In some aspects, the step of depositing a second doped layer stack comprises depositing a third mask layer on top of the second doped layer stack. The third mask layer is structured such that areas of the second doped layer stack surrounding in projection the top portion are exposed. In other words, the mask may cover the projection of the top portion including the planar quantum well structure. A p-type dopant, for example Zn is subsequently deposited into the exposed areas such that the p-type dopant causes a QWI within the quantum well structure on the inclined sidewall.

For this purpose and to achieve a better control of the QWI process, the step of diffusing comprises depositing the p-type dopant onto the exposed areas at a first temperature and then subsequently diffusing the deposited p-type dopant into the exposed areas at a second temperature, the second temperature optionally higher than the first temperature.

### BRIEF DESCRIPTION OF THE DRAWINGS

Further aspects and embodiments in accordance with the proposed principle will become apparent in relation to the various embodiments and examples described in detail in connection with the accompanying drawings in which

FIG. 1 shows a schematic view of an optoelectronic device;

FIG. 2 illustrates a detailed view of an optoelectronic device in accordance with some aspects of the present disclosure; and

FIGS. 3A to 3I shows various steps of a processing method of an optoelectronic device in accordance with some aspects of the present disclosure.

### DETAILED DESCRIPTION OF ILLUSTRATIVE EMBODIMENTS

The following embodiments and examples disclose different aspects and their combinations according to the proposed principle. The embodiments and examples are not always to scale. Likewise, different elements can be displayed enlarged or reduced in size to emphasize individual aspects. It goes without saying that the individual aspects of the embodiments and examples shown in the figures can be combined with each other without further ado, without this contradicting the principle according to the invention. Some aspects show a regular structure or form. It should be noted that in practice slight differences and deviations from the ideal form may occur without, however, contradicting the inventive idea.

In addition, the individual figures and aspects are not necessarily shown in the correct size, nor do the proportions between individual elements have to be essentially correct. Some aspects are highlighted by showing them enlarged. However, terms such as “above”, “above” “below”, “below” “larger”, “smaller” and the like are correctly represented with regard to the elements in the figures. Therefore, it is possible to deduce such relations between the elements based on the figures.

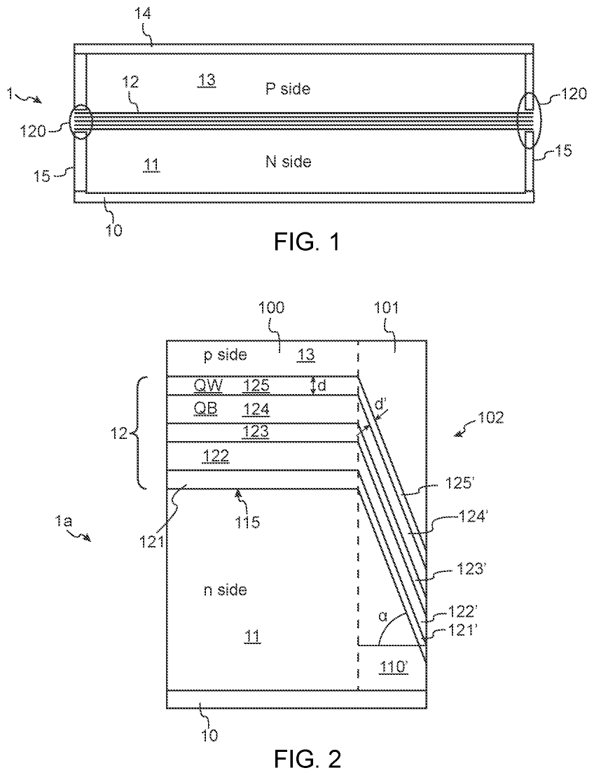

FIG. 1 shows an optoelectronic device illustrating some issues of conventional optoelectronic devices. The optoelectronic device is grown onto substrate 10 and comprises an n-doped layer stack 11 as well as a p-doped layer stack 13. Between the n-doped layer stack 11 and the p-doped layer stack 13, a quantum well structure 12 is arranged. Most layer stacks 11 and 13 can comprise different individual layers of the same dopant type having different concentrations. For example, n-doped layer stack 11 may contain several n-doped layers with different concentrations including a highly n-doped current distribution layer adjacent to substrate 10. Likewise p-doped layer stack 13 may comprise a current distribution layer not shown herein adjacent to top transparent layer 14. Top transparent layer 14 can be implemented as a conductive transparent layer, for example, a made of ITO suitable to transport of the charge carrier towards the current distribution layer within layer stack 13.

Quantum well structure 12 includes a multi-quantum well having a plurality of quantum well layers separated by corresponding barrier layers. Depending on the implementation, the p-doped layer stacks 11 and 13 may be arranged directly adjacent to quantum well structure 12. In an alternative embodiment, the quantum well layer structure may comprise one or more intrinsic layers adjacent to the respective layer stacks 11 or 13, respectively. The intrinsic layer in this regard can include the same base material layer as the respective layer stack.

Such optoelectronic devices will be mesa-structured during the course of its manufacturing process, thus forming sidewalls 15. Sidewalls 15 are in some instances covered by an insulating layer or otherwise treated to provide a smooth surface and reduce impurities close to the surface. In some embodiments, the outer portions close to the sidewalls 15 of the respective device may also comprise additional material, in order to provide a quantum well intermixed region close to the edges of the quantum well structure 12 in area 120. Nevertheless, the respective surface portion of the quantum well structure 12 in area 120 contain impurity and non-saturated crystal bonds.

Hence, the surface structure can result in a non-radiant recombination of charge carriers being inserted into the quantum well structure 12. Area 120 with the impurities and surface effects circumferences of the optoelectronic device. With small devices, the portion of the circumferential area 120 increases with regard to the central portion of the quantum structure 12. As a result, the amount of non-radiant recombination also increases with respect to radiant recombination, and the internal quantum efficiency of the device decreases.

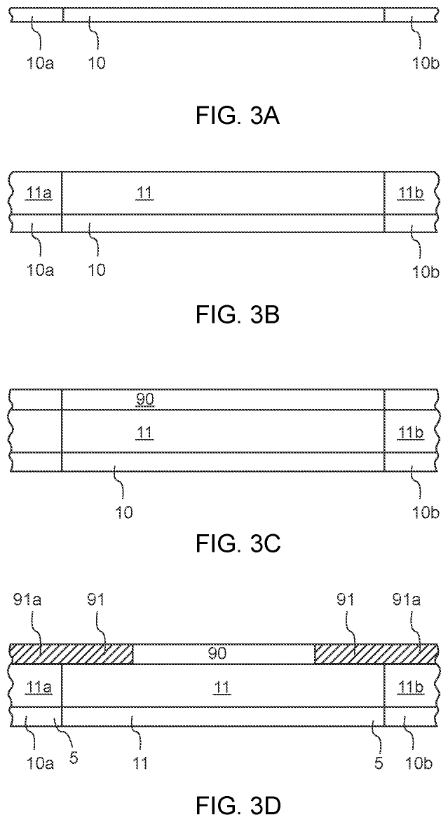

The inventors now propose an idea to prevent charge carriers from reaching the respective surface regions and area 120, thus reducing a non-radiant recombination and increasing the internal quantum efficiency. FIG. 2 illustrates a respective example showing a portion of an optoelectronic device in accordance with the proposed principle.

The optoelectronic device is divided into a first central region 100 and a circumferential region 101 surrounding the first region 100. Circumferential region 101 is limited by a mesa 102. The device comprises a substrate 10, on which an n-doped layer stack is deposited upon forming n-doped layer stack 11 in the central region and n-doped layer stack 110′ in the circumferential region 101. Similar to the embodiment in conventional optoelectronic devices, the n-doped layer stack in both regions 11 and 110′ can comprise different layers with different dopant concentration to provide uniform current distribution and injection into the active region 12. However, in contrast to conventional devices, the optoelectronic device in accordance with the proposed principle is separated into said central first portion 100 and in the surrounding second portion 101. The second portion 101 circumferences the central portion and is arranged between the mesa 102 of the optoelectronic device and the respective central portion 100.

As illustrated in the embodiment of FIG. 2, the portion 110′ of the n-doped layer stack 110′ includes the same concentration of dopants as the adjacent layer stack in the central portion, but also an inclined surface. Said surface is inclined with the angle α and defined as the angle between the surface of the portion 110′ and top surface 115 of layer stack 11 within the central region.

The central portion 100 includes the quantum well structure 12 as active region comprising a plurality of quantum well layers 121, 123 and 125 separated by respective quantum well barrier layers 122 and 124, respectively. A thickness d in the quantum well layers 121, 123 and 125 is set to be equal, but also can be chosen differently. The thickness of the quantum barrier 120 to 124 is a little larger than the thickness d of the respective quantum well layers, but also can be chosen differently. Quantum barrier material is different from quantum layer material. The given thickness d with the quantum well layers 121, 123 and 125 will cause a certain bandgap for the respective quantum well layers. It has been shown that the thickness of the quantum well layers directly influences their respective band gap. The smaller the thickness d becomes, the larger the respective bandgap of the layer will be.

This effect is now used to generate and create an artificial increase in the band gap of the respective quantum well layers in the second circumferential portion 101 of the optoelectronic device in accordance with the proposed principle. For this purpose, the quantum well layers of the quantum well structure and active region 12 are continued along the circumferential portion and tilted with the same angle in regards to the top panel surface 115.

As a result, first quantum well layer 121 on top surface of layer stack 11 extends on the inclined surface of portion 110′ as quantum well layer 121′. Likewise, quantum well barrier 121 extends on the tilted surface as quantum well barrier 121′ Simply speaking, the quantum well structure 12 on top layer surface of the n-doped layer stack 11 is continued on the tilted surface along portion 110′ of the layer stack. However, due to the angle α, thickness d′ of the respective quantum wells as well as the quantum well barriers on the tilted surface now changes and become thinner. The thinner thickness of the quantum well layers on the tilted surface, namely quantum the layers 121′, 123′ and 125′ will cause an increase in their respective bandgaps. The thickness d′ (as well as the overall thickness of structure 12 on the tilted surface) depends on the angle α and can be expressed in first order as d′=d×cos(α).

Consequently, charge carriers getting close to the circumferential portion 101 will now face a larger bandgap and can reach the surface area close to the mesa structure 102 only by overcoming the additional bandgap difference created by the tilted surface. This difference is adjusted to some extend by the angle and the tilt of the surface of portion 110′ in circumferential region 101. The larger the tilt is, the higher the difference becomes.

Finally, the cone in region 101 is first filled with low p-doped material, then high p-doped material is grown in layer 13 in the central portion 100 as well as in the side portion 101. As stated previously p-doped layer can include a current distribution layer (not shown herein). However it is suitable that current distribution layer is mainly located on top (in projection above) the active region 12 in the central portion 100.

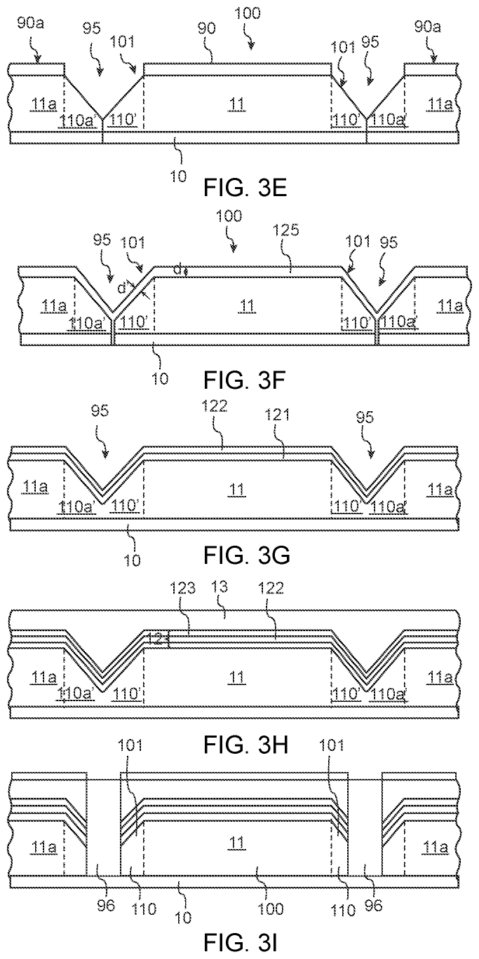

FIG. 3A to 3I illustrate various manufacturing and processing steps of providing an optoelectronic device in accordance with some aspects of the proposed principle. In FIG. 3A, a growth substrate 10 is provided. In the illustration, the growth substrate is divided into separate portions 10a, 10 and 10b for illustrating purposes indicating the borders and later separation lines between the different optoelectronic devices being manufactured on the substrate.

The growth substrate is selected to be suitable for the base material. The growth substrate 10 further comprises several smoothing and preprocessing layers for subsequent growth of the base material. In a next step shown in FIG. 3B, a layer stack 11 is deposited on the growth substrate. The layer stack 11 includes different concentration of n-type dopants such as to provide a current distribution and injection layer. For this purpose, the deposition process is performed by a chemical vapour deposition process, in which additional metal atoms or ions as dopants are induced. For example, as an n-type dopant Selene or Telluric or other suitable materials can be used. Dopant concentration can be adjusted by changing the dopant material throughout the deposition process.

In some embodiments, the layer stack 11 comprises an intrinsic layer of the base material as a top layer that is as the last deposited layer.

In FIG. 3C mask layer 19 is arranged on the top surface of n-doped layer stack 11. The mask layer 90 is subsequently structured in FIG. 3D to form a structured mask layer with a central portion 90, surrounded by exposed portions 91. Consequently, the structured mask with its central portion 90 will define the first and second region of each of the optoelectronic devices grown on the substrate. The circumferential exposed mask portions 91 are subsequently removed to expose the underlying portions of the n-doped layer.

In a subsequent step shown in FIG. 3E, first shallow mesa structures 95 are etched into the exposed areas, thus defining an inclined surface in the second region 101 in circumferential portions 110′ of the n-doped layer stack. The results are illustrated in FIG. 3D. Hence, for this process photolithographic steps are used to provide a tilted surface in the second region on the n-doped layer stack, partly removing material form said stack. The shallow mesa structure 95 circumferences the respective layer stacks 11 and 11a later forming the optoelectronic devices in accordance with some aspects of the proposed principle. The angle of inclination on the surface of portion 110′ depends on the used etchant and various etching parameters. As shown in FIG. 3E, the mesa structure 95 does not reach the substrate surface 10 leaving a small portion of n-doped material unetched.

After the formation of the shallow mesa structure 95, the remaining mask layer, 90 and 90a are removed. In a subsequent step, the first layer of the quantum well structure 12 forming the active region is deposited on the n-doped layer stack. During the deposition process, the material grows on the top surface of layer stack 11 as well as on the sidewalls on portions 110. However, as shown in FIG. 3F, the growth rate on the top surface is higher than the growth rate on the sidewalls resulting in a larger thickness d on the top surface of layer stack 11 in central region 100 compared to the sidewall portion 110 and 110a. The thickness difference is given by the angle of the tilted surface. Generally speaking, the thickness difference becomes larger, the larger the angle defined by the tilted surface and the planar top surface becomes. In first approximation, the thickness d′ is proportional to the cosine of the above-mentioned angle.

During the deposition process, the shallow mesa structures is at least partially filled with the material of the first layer of the quantum well structure, slowly filling the gap.

After deposition of the first quantum well layer material, barrier layer material is deposited on the first a quantum well layer material both on the top surface layer as well as in the shallow mesa structure 95. Similar to the previous deposition process, the growth rate on the top surface layer larger than on the sidewalls resulting in a larger thickness thereupon. The result is again shown in FIG. 3G. The process of depositing a barrier layer material as well as quantum layer material on top of each other, slowly filling the mesa structure, can be repeated until the desired multi quantum well layer structure is formed on top surface layer as well as in the mesa structures 95.

In this regard, it should be noted, that the depth of the mesa structure as well as its lateral size will determine the inclination angle and therefore also the thickness of the respective layer material deposited in the mesa structure. If the number of quantum well layers and quantum well area layers are becoming too large for a respective mesa depth, the mesa structure could be overgrown, diminishing the result of tilted surface and the increased band gap caused by it.

In a subsequent process steps illustrated in FIG. 3H, a p-doped layer stack 13 is deposited on the last quantum well layer 123 forming the quantum well structure 12. As shown in FIG. 3H, the quantum structure 12 comprises two quantum well layers 121 and 123 separated by a quantum well barrier layer 122. The thickness of the respective quantum well layers is decreased within the shallow mesa structure 95 compared to the thickness of the respective layers on the top surface of layer stack 11 in the central region.

Similar to the deposition of the n-doped layer stack 11, the p-doped layer stack 13 comprises several different layers of varying dopant concentration to provide a current distribution layer for charge injection into quantum well structure 12 in the central region. The p-doped layer 13 is deposited until substantially flat surface is reached and at least until the shallow mesa portions 95 are completely covered with the base material of p-doped layer 13. The p-doped layer is reduced to smoothen the surface.

In some instances, p-dopants can be introduced, particularly on the central portion in order to provide current and injection distribution into active region 12. In addition Zn as dopant can be injected into the circumferential second region to provide a quantum well intermixing in the tilted quantum well structure in the second region. For this purpose and not shown herein, a mask layer is deposited on the p-doped layer stack 13 with the first region covered by the mask material, and areas in the second region adjacent to the first region are being exposed. Then, Zn as dopant is deposited on the exposed areas and subsequently diffused into the second region until a quantum well intermixing of the inclined quantum well layers are achieved. Deposition and diffusion of Zn into the inclined quantum well layers are done at different temperatures. The additional step further increase the band gap and thus the difference between the band gaps in the second region and the band gaps in the first region.

In a subsequent step, a hard mask is deposited on top of the p-doped layer covering the respective central portion of each optoelectronic device and extending partially to the adjacent areas, also covering a portion of the shallow mesa structure. The hard mask is illuminated and exposed portions removed as to expose areas within the shallow mesa structure. The exposed area in the shallow mesa are subsequently etched to provide a deep mesa 96 until the substrate surface is reached and the individual optoelectronic devices separated. The resulting arrangement is illustrated in FIG. 3I, in which the central region 100 with a layer stack 11 is surrounded by a circumferential portion 101. Subsequently the hard mask can be removed, and the optoelectronic devices re-bonded to remove the growth substrate 10 and process the n-doped layer to provide n-contacts thereupon.

1.-21. (canceled)

22. An optoelectronic device comprising:
a semiconductor body with a layer stack, wherein the layer stack has a first region and a surrounding second region extending to a sidewall of the layer stack, the layer stack comprising:
a first n-doped layer;
a quantum well structure arranged on the first n-doped layer; and
a p-doped layer arranged on the quantum well structure,
wherein the quantum well structure extends along a lateral plane within the first region of the layer stack,
wherein the quantum well structure extends within the second region on an inclined surface of one of the n-doped layer and p-doped layer with regards to the lateral plane to the sidewall of the layer stack such that a thickness of the quantum well structure within the second region is smaller than a thickness of the quantum well structure within the first region, and
wherein the quantum well structure within the second region comprises a p-type dopant causing a quantum well intermixing within the quantum well structure.

23. The optoelectronic device according to claim 22, wherein a bandgap of the quantum well structure in the first region is smaller than a bandgap of the quantum well structure in the second region.

24. The optoelectronic device according to claim 22, wherein the quantum well structure comprises an intrinsic layer at least in the first region adjacent to the n-doped layer and/or the p-doped layer.

25. The optoelectronic device according to claim 22, wherein the inclined surface of the n-doped layer and/or an area adjacent to the inclined surface of the n-doped layer within the second region comprise(s) a larger dopant concentration than a dopant concentration in the first region of the n-doped layer adjacent to the quantum well structure.

26. The optoelectronic device according to claim 22, wherein a p-type dopant extends partially into the n-doped layer causing a shift of a depletion region towards the n-doped layer.

27. An optoelectronic device comprising:
a semiconductor body with a layer stack, the layer stack has a first region and a surrounding second region extending to a sidewall of the layer stack, the layer stack comprising:
a first n-doped layer;
a quantum well structure arranged on the first n-doped layer; and
a p-doped layer arranged on the quantum well structure,
wherein the quantum well structure extends along a lateral plane within the first region of the layer stack,
wherein the quantum well structure extends within the second region on an inclined surface of one of the n-doped layer and p-doped layer with regards to the lateral plane to the sidewall of the layer stack such that a thickness of the quantum well structure within the second region is smaller than a thickness of the quantum well structure within the first region, and
wherein a doping concentration of the n-doped layer in the second region is lower that a doping concentration in the first region.

28. The optoelectronic device according to claim 27, wherein a bandgap of the quantum well structure in the first region is smaller than a bandgap of the quantum well structure in the second region.

29. The optoelectronic device according to claim 27,
wherein the quantum well structure comprises a first quantum well and a second quantum well separated by a quantum well barrier, or
wherein the quantum well structure comprises a first quantum well arranged between two quantum well barriers.

30. The optoelectronic device according to claim 27, wherein the quantum well structure comprises an intrinsic layer at least in the first region adjacent to the n-doped layer and/or the p-doped layer.

31. The optoelectronic device according to claim 27, wherein a thickness of the quantum well structure within the second region is based on an inclination angle between the inclined surface and the lateral plane.

32. The optoelectronic device according to claim 27, wherein a diameter of the inclined surface parallel to lateral plane increases with an increasing distance towards the quantum well structure within the first region.

33. The optoelectronic device according to claim 27, wherein the inclined surface of the n-doped layer and/or an area adjacent to the inclined surface of the n-doped layer within the second region comprise(s) a larger dopant concentration than a dopant concentration in the first region of the n-doped layer adjacent to the quantum well structure.

34. The optoelectronic device according to claim 27, wherein the sidewall of the layer stack comprises a mesa structure.

35. The optoelectronic device according to claim 27, further comprising a p-type dopant deposited in the quantum well structure within the second region causing a quantum well intermixing thereof.

36. The optoelectronic device according to claim 27, wherein a p-type dopant extends partially into the n-doped layer causing a shift of a depletion region towards the n-doped layer.

37. The optoelectronic device according to claim 27, wherein the n-doped layer and/or the p-doped layer comprises a base material selected from the group consisting of GaN, AlGaN, AlGaInP, AlGaInN and AlGaP.

38. A method for processing an optoelectronic device, the method comprising:
providing a growth substrate;
depositing a first doped layer stack on the growth substrate;
mesa-structuring the first doped layer stack to provide a top portion surrounded by an inclined sidewall having an angle of less than 90;
depositing a quantum well structure on the mesa-structured first doped layer such that a thickness of the quantum well structure on the inclined sidewall is smaller than a thickness of the quantum well structure on the top portion;
depositing a second doped layer stack on the quantum well structure;
depositing a structured mask on the second doped layer stack; and
mesa structuring the optoelectronic device as to provide sidewalls thereof exposing edge portions of the quantum well structure on the inclined surface,
wherein depositing the second doped layer stack comprises:
depositing a third mask layer on top of the second doped layer stack,
structuring the third mask layer such that areas of the second doped layer stack surrounding in projection the top portion are diffusing the deposited exposed,
diffusing a p-type dopant into exposed areas such that the p-type dopant causes a QWI within the quantum well structure on the inclined sidewall.

39. The method according to claim 38, wherein depositing the second doped layer stack comprises:
depositing a third mask layer on top of the second doped layer stack,
structuring the third mask layer such that areas of the second doped layer stack surrounding in projection the top portion are diffusing the deposited exposed, and
diffusing a p-type dopant into exposed areas such that the p-type dopant causes a QWI within the quantum well structure on the inclined sidewall.

40. The method according to claim 39, wherein the diffusing comprises:
depositing the p-type dopant onto the exposed areas at a first temperature, and
diffusing the deposited p-type dopant into the exposed areas at a second temperature, the second temperature being optionally higher than the first temperature.

41. A method for processing an optoelectronic device, the method comprising:
providing a growth substrate;
depositing a first doped layer stack on the growth substrate;
mesa-structuring the first doped layer stack to provide a top portion surrounded by an inclined sidewall having an angle of less than 90°;
depositing a quantum well structure on the mesa-structured first doped layer such that a thickness of the quantum well structure on the inclined sidewall is smaller than a thickness of the quantum well structure on the top portion;
depositing a second doped layer stack on the quantum well structure;
depositing a structured mask on the second doped layer stack; and
mesa structuring the optoelectronic device as to provide sidewalls thereof exposing edge portions of the quantum well structure on the inclined surface,
wherein a doping concentration of the first doped layer below the inclined sidewalls is smaller than a doping concentration of the first doped layer below the top portion.

42. The method according to claim 41, wherein mesa-structuring the first doped layer stack comprises:
depositing a first mask layer on the first doped layer stack,
structuring the first mask layer such that areas of the first doped layer stack surrounding the top portion are exposed, and
removing material in exposed areas to form the inclined surface.

43. The method according to claim 41, wherein depositing the structured mask on the second doped layer stack comprises:
depositing a second mask layer on the second doped layer stack,
structuring the second mask layer such that areas of the second doped layer stack, which in projection surrounds the top portion and areas surrounding the top portion are exposed, and
removing material in exposed areas.

44. The method according to claim 41, wherein the depositing the first doped layer stack or the second doped layer stack comprises depositing a semiconductor base material using MOCVD or MOVPE processes with respective different dopant concentrations.

45. The method according to claim 41, wherein depositing the first doped layer stack and/or the second doped layer stack comprises depositing an intrinsic layer of a base material of the respective first and/or second doped layer stack, the intrinsic layer being adjacent to the quantum well structure.

46. The method according to claim 41, wherein depositing the quantum well structure comprises depositing one or more quantum layers between respective quantum well barrier layers, the quantum well barrier layers having a larger bandgap than the quantum well layers.

47. The method according to claim 41, wherein a thickness of the quantum well layer structure is based on the inclination angle between the sidewalls of the first doped layer stack and a top planar surface of the first doped layer stack.

48. The method according to claim 41, wherein an angle between the sidewalls of the optoelectronic device and the top surface of the first doped layer stack is larger than an angle between the inclined sidewalls of the first doped layer stack and the top surface of the first doped layer stack.

49. The method according to claim 41, wherein depositing the second doped layer stack comprises:
depositing a third mask layer on top of the second doped layer stack,
structuring the third mask layer such that areas of the second doped layer stack surrounding in projection the top portion are diffusing the deposited exposed, and
diffusing a p-type dopant into exposed areas such that the p-type dopant causes a QWI within the quantum well structure on the inclined sidewall.

50. The method according to claim 49, wherein the diffusing comprises:
depositing the p-type dopant onto the exposed areas at a first temperature, and
diffusing the deposited p-type dopant into the exposed areas at a second temperature, the second temperature being optionally higher than the first temperature.
